(19) United States
(12) Patent Application Publication
(10) Pub. No.: US 2005/0186920 A1
(43) Pub. Date: Aug. 25, 2005

(54) Apparatus for and method of noise suppression and dithering to improve resolution quality in a digital RF processor

(75) Inventors: Robert B. Staszewski, Garland, TX (US); Dirk Leipold, Plano, TX (US); Khurram Muhammad, Richardson, TX (US); Sameh S. Rezeq, Dallas, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/062,254

(22) Filed: Feb. 18, 2005

Related U.S. Application Data
(60) Provisional application No. 60/546,249, filed on Feb. 19, 2004.

(51) Int. Cl. H04B 1/68; H03C 3/00; H04B 1/04; H04B 1/06

(52) U.S. Cl. 455/114.1; 455/109; 455/570; 455/285; 455/302

(57) ABSTRACT

A novel apparatus for and a method of noise and spurious tones suppression in a digital RF processor (DRP). The invention is well suited for use in highly integrated system on a chip (SoC) radio solutions that incorporate a very large amount of digital logic circuitry. The noise suppression scheme eliminates the noise caused by various on chip interference sources transmitted through electromagnetic, power, ground and substrate paths. The noise suppression scheme permits an all digital PLL (ADPLL) to operate in such a way to avoid generating the spurs that would normally be generated from the injection pulling effect of interfering sources on the chip. The frequency reference clock is retimed to be synchronous to the RF oscillator clock and used to drive the entire digital logic circuitry of the DRP. This ensures that the different clock edges throughout the system will not exhibit mutual drift. A method of improving the resolution quality of a time to digital converter within the ADPLL is also taught. The method dithers the reference clock by passing it through a delay circuit that is controlled by a sigma-delta modulator. The dithered reference clock reduces the affect on the phase noise at the output of the ADPLL due to ill-behaved quantization of the TDC timing estimation.

### REFERENCE TO RELATED APPLICATIONS

This application claims priority to U.S. Provisional Application Ser. No. 60/546,249, filed Feb. 19, 2004, entitled “Clock Retiming and Synchronization Method for Noise Suppression in the Digital Radio Processor”, incorporated herein by reference in its entirety.

### FIELD OF THE INVENTION

The present invention relates to the field of data communications and more particularly relates to an apparatus for and method of suppressing noise in a digital RF processor (DRP)™ and an apparatus for and method of dithering to improve the resolution quality of a time to digital converter in a DRP.

### BACKGROUND OF THE INVENTION

It is well known that oscillatory systems are susceptible to injection pulling and injection locking. As an example, it has been observed that humans left in isolated bunkers reveal a free running sleep-wake period of about 25 hours. A natural day on Earth is 24 hours, however, and humans exposed to this 24-hour cycle are injection locked to the Earth's natural cycle.

Injection locking occurs when the oscillations of a first system influences a second system to the extent where the second system no longer oscillates at its own natural frequency but rather at the frequency of the first system. There are applications where injection locking is useful such as frequency division, quadrature generation and oscillators with finer phase separations.

Injection pulling, on the other hand, is almost always undesirable. Injection pulling occurs when the injected signal of a first system lies out of but not very far from the oscillator lock range of a second system.

Consider an all-digital phase locked loop (ADPLL) based digital RF processor (DRP)™ transmitter. A diagram illustrating a prior art example of a fractional-N synthesizer using a sigma-delta modulated clock divider is shown in FIG. 1. The synthesizer (or PLL), generally referenced 10, comprises phase/frequency detector 12, loop filter 14, voltage controlled oscillator (VCO) 16, frequency divider 18 and sigma-delta modulator 20.

Fractional-N synthesizers, well known in the art, are able to increment their output frequencies by fractions of the reference frequency (FREF), thus allowing the output frequency to be much greater than the required channel spacing. The permits a wide loop filter at the expense of fractional frequency spurs. This results in improved loop dynamics and attenuation of oscillator-induced noise. The bandwidth of the PLL is typically set at approximately 10% of the reference frequency FREF in order to avoid any significant feedthrough of the reference tone and may span several channels. In response to a change in a frequency control word (FCW), the PLL output frequency settles to the programmed value with a certain time constant inversely related to the bandwidth of the loop.

A fractional-N PLL is capable of achieving an arbitrarily fine time-averaged frequency division ratio by modulation of the instantaneous division ratio of 1/N+b. In operation, the frequency division is altered to N+b by the introduction of a control signal b(t) generated by the sigma-delta modulator 20. The resulting average division ratio will be increased by the duty cycle of the N+b division.

The phase error of the phase detector causes VCO fractional spurs at multiples of the offset frequency. Several prior art techniques exist to suppress the fractional spurs, such as the analog fractional-N compensation scheme wherein an accumulator and a digital to analog converter (DAC) are used and based on the observation that the phase error perturbation is periodic and deterministic and can be canceled out by a tracking circuit. This form of correction is known as phase interpolation. The fractional spurs are reduced to the extent that the phase interpolation signal exactly matches the phase error. In practice, however, it is difficult to achieve fractional spurs lower than −70 dBc, thus requiring a precision DAC and carefully designed phase detector and sampler circuitry. This interpolation scheme, however, is suitable is most applications due to its analog complexity.

Typically, a frequency synthesizer requires at least two clocks. One is a reference clock and the other is the variable output clock. The frequency synthesizer performs a multiplication with the frequency reference clock. Thus, a typical frequency synthesizer, regardless of whether it is based on a PLL architecture or some other structure, needs to have a reference clock and a variable clock, i.e. the clock that is being generated. One problem associated with a generalized frequency synthesizer is that it is typically required to support non-integer frequency multiplication. With non-integer frequency multiplication, if one requires to support an arbitrarily generated frequency, the generated frequency may lie close to the frequency reference and frequency beating may occur.

This is especially common in an integrated circuit (IC) implementation, since an IC has a substrate that is not perfectly isolated. Further, the power traces, ground traces, ground planes, bonding wires, etc. typically behave as small antennas, even if there is no leakage through the substrate. In addition, noise and other interference can travel from part of the IC to another.

Typically, the portion of the circuit it is desirable to protect the most is the RF oscillator (i.e. voltage controller oscillator, digitally controller oscillator). This is so because it is common that the transmitter is subject to very strict requirements on the spurious levels and phase noise of the transmitted output signal. The oscillator is constructed as an LC tank structure with second order characteristics. This means it has a coil with several winding, e.g., 3 to 5, which take up a relatively large amount of chip space. It is not unusual for a single integrated inductor to take up the space of 50,000 gates. Therefore, the coil is very sensitive to noise and interference pick up.

Consider an interference that is not coherent with the RF oscillator. If the frequency of the interference is far enough away from the center frequency of the LC tank, it will be rejected due to the selectivity, i.e. second order filtering, of the tank. An interference exactly at the center frequency of the oscillator is also not problematic since it is likely to be masked by the huge energy spike at the center frequency of the tank. If the interferer, however, is very close to the center frequency of the oscillator and its energy is sufficiently high, then it will create an injection pulling force on the oscillator output and attempt to pull the oscillator frequency towards the frequency of the interference and will create output spurs in the process. These spurs could be problematic if they happen to be at the wrong location at a high enough amplitude. It is thus desirable to minimize these spurious frequencies by eliminating the injection pulling force. A more in depth discussion of injection pulling and locking can be found in B. Razavi, “A Study of Injection Locking and Pulling in Oscillators”, IEEE Journal of Solid State Circuits, Vol. 39, No. 9, September 2004, pp. 1415-1424.

A timing diagram illustrating the injection pulling force affected by a fractional clock (i.e. FREF) on the RF oscillator output clock (i.e. FVCO) in the prior art example of FIG. 1 is shown in FIG. 2. In this example, the RF oscillator clock frequency is 2¼ times that of the frequency reference (FREF) clock (i.e. the fractional clock). The positive clock edges for the oscillator clock are shown in the upper waveform and for the fractional clock in the middle waveform. The resultant injection pulling force is shown in the lower waveform.

The VCO or DCO portion of the transceiver is the most sensitive circuit in most wireless systems and is very sensitive to disturbance edges. The edges of the interfering clock (i.e. FREF) try to pull or effect the oscillations of the large LC tank of the DCO. The effect of the frequency reference clock is to pull the edges of the oscillator waveform towards the reference frequency clock edges. The pulling force of the interference is a certain function of the difference between the closest edges of the two clocks. Here, however, it is assumed to be proportional, even though the dependency may be more complex.

Assuming a frequency division ratio of 2¼, there will be on average 2¼ oscillator (CKV) clock edges per fractional clock (FREF) edge. Therefore, the first FREF edge occurs ¼ after time tick 2 but before tick 3. The next event will be at 4½, 6¾, 9 and so on in a repeatable, known pattern. Note that the distances between the two clock edges are not random. The distances vary but they are predictable. It is noted that the RF oscillator and reference frequencies do not need to be close to each other.

Thus the problem with this prior art circuit is that oscillator is sensitive to interference from outside the DCO. The clock edges represent phase and the phase has a certain sensitivity transfer function associated with it. A disturbance that falls exactly on the edges of the oscillator clock does not effect it because the disturbance is perfectly aligned with the oscillator edges. A disturbance that does not fall exactly on the edges does have an effect on the phase. Note that the injection pulling may be caused by a harmonic of the lower frequency clock (i.e. the fractional frequency reference clock) which falls in the frequency neighborhood of the oscillator. It is also noted that the output clock edge of the oscillator is a proxy for the internal phase state of the LC tank. Due to the propagation delay of the clock, the observed clock edge might be significantly delayed with respect to the timing of the internal phase of the LC tank and this delay might not be known with sufficient accuracy.

The closeness of the edges of the oscillator and frequency reference clocks determines the degree of the injection pulling force which has a certain frequency associated with it. With reference to FIG. 2, the interfering clock (i.e. FREF clock) has a frequency that is 2¼ times lower than the oscillator frequency. Thus each edge of the interfering clock pulls either every second or third oscillator edge.

At time 2¼, the pulling force is +¼. The edge event at time 4½ is exactly equidistance between edges 4 and 5 of the oscillator clock, thus both edges are being pulled equally resulting in zero pulling force effect. The edge event at time 6¾ is ¼ before the edge at time 7. The pulling force is −¼. The edge event at time 9 is aligned with the oscillator edge hence the pulling force here too is zero. The frequency clock edge events then repeat in the same pattern every four frequency reference clock edges. Thus there is a certain frequency pulling dependency which results in the creation of spurs in the output. The higher frequency of the DCO will thus be pulled by this pulling frequency which is at a much lower frequency. For example, the DCO frequency may be on the order of gigahertz, while the beating frequency may be much lower on the order of tens or hundreds of kilohertz. The effect on the oscillation frequency of the DCO subject to injection pulling is that the output frequency exhibits spurious tones by these tens or hundred of kilohertz. Thus it becomes impossible to tell the difference between a spur caused by injection pulling or the desired signal. This may violate any communication standard such as GSM or Bluetooth likely making compliance with any standard impossible.

Note that the injection pulling mechanism is dependent on the fractional part of the frequency division ratio N.

$$N = {N}_{i} + {N}_{f} = \frac{{f}_{0}}{{f}_{1}} \qquad ( 1 )$$

where

Nᵢ is the integer part of N;

N_{f} is the fractional part of N;

f₀ is the oscillator clock frequency;

f₁ is the interfering clock frequency;

If Nf=0, there is no injection pulling. If N_{f} is close to zero, a positive beating frequency f_{beat}=N_{f·f}₁ results. N_{f} close to one results in a negative beating frequency f_{beat}=−(1−N_{f})·f₁. The terms ‘positive’ and ‘negative’ indicate the direction of change of the clock edge pulling force. The higher values of f_{beat} are not likely to be a problem because they are too fast to coherently pull the oscillator.

It is noted that a constant pulling force does not present a problem because, due to different propagation delays of the various interferers through power, ground and substrate paths, there will be a non-zero equilibrium state of the delays.

### SUMMARY OF THE INVENTION

The present invention provides a solution to the problems of the prior art by providing an apparatus for and a method of noise suppression in a digital radio receiver and transmitter, or transceiver. This noise, including spurious tones, is particularly noticeable in a highly integrated CMOS based system on a chip (SoC) radio solution that incorporates a very large amount of digital content. The noise suppression scheme of the present invention is effective to eliminate the noise caused by the various on chip interference sources transmitted through power, ground and substrate paths. The noise suppression scheme permits an all digital PLL (ADPLL) to operate in such a way so as to avoid generating the spurs that would normally be generated from the injection pulling effect of interfering sources on the integrated circuit chip.

The solution of the problems of the prior art as taught by the present invention is to operate the entire radio, e.g., a digital RF processor, the digital baseband processor and the application processor, in a clock synchronous mode wherein every clock in the system is either derived from or synchronized to the RF oscillator clock. Thus, the frequency reference clock is made synchronous to the oscillator clock and this retimed frequency reference clock is used to drive the entire digital logic circuitry of the DRP chip. This ensures that the different clock edges throughout the system will not exhibit mutual drift. As described in the Background Section of this document, the mutual drift of the oscillator and clock edges is especially damaging to the system performance of the transmitter and the receiver because it subjects the RF oscillator to injection pulling forces and causes time varying noise coupling in sampled systems.

The noise suppression mechanism of the present invention comprises retiming the frequency reference (FREF) clock such that the edges of the retimed frequency reference clock are aligned with the RF oscillator clock. The resultant retimed frequency reference clock is then used to drive the digital logic. In addition, the invention is operative to retime the ADPLL clock outputs that generate high frequency ADPLL and processor clocks.

The present invention solves the noise and interference problem of injection pulling that effects transmitter and receiver performance which is caused by the high digital content of modern system on chip integrated radios. The invention provides a cost effective solution to this problem which would otherwise require solutions such as stacking die packages in which the RF and analog circuitry is physically isolated from the digital circuitry. Such a solution would be very expensive and not likely to be as effective thus making it impractical to implement.

An embodiment is presented wherein the amount of circuitry operating strictly on the FREF clock in the FREF originating digitally controlled crystal oscillator (DCXO) circuit is minimized by clocking the digital logic with the retimed frequency reference clock.

The mechanism also comprises the capability of generating an arbitrary frequency clock by dividing the RF oscillator edges using a fractional N divider. An embodiment incorporating an application of the invention comprises utilizing the directly derived RF oscillator clock whereby the digital receive data path circuitry is operated on a simple divide by integer N clock. The sample rate conversion from a channel dependent rate to a fixed rate of the symbol multiple is performed by an interpolator or resampler.

The present invention also comprises a method and apparatus of improving the resolution quality in a time to digital converter (TDC). The TDC is a component in the ADPLL that functions to measure the fractional time delay difference between the reference clock and the next rising edge of the RF oscillator clock. The quantization of timing estimation performed by the TDC affects the phase noise at the output of the ADPLL. The predominant contributor to TDC error is quantization noise. With proper design of the TDC, the noise in a deep-submicron CMOS process is low and it is expected to be sufficient for cellular applications. Operating the ADPLL at or near the integer-N channels, however, produces peculiar behavior due to the insufficient randomization of the TDC quantization noise.

A solution to this problem taught by the present invention is to randomize the instantaneous value of the timing difference using the well-known sigma-delta techniques. The FREF clock is passed through a delay circuit to generate a dithered FREF clock signal. The delay circuit is controlled by a 5^{th} order sigma-delta modulator, which may be scaled down to a lower order.

Note that many aspects of the invention described herein may be constructed as software objects that are executed in embedded devices as firmware, software objects that are executed as part of a software application on either an embedded or non-embedded computer system running a real-time operating system such as WinCE, Symbian, OSE, Embedded LINUX, etc. or non-real time operating system such as Windows, UNIX, LINUX, etc., or as soft core realized HDL circuits embodied in an Application Specific Integrated Circuit (ASIC) or Field Programmable Gate Array (FPGA), or as functionally equivalent discrete hardware components.

### BRIEF DESCRIPTION OF THE DRAWINGS

The invention is herein described, by way of example only, with reference to the accompanying drawings, wherein:

FIG. 1 is a diagram illustrating a prior art example of a fractional-N synthesizer using a sigma-delta modulated clock driver;

FIG. 2 is a timing diagram illustrating the injection pulling force effect by a fractional clock on the RF oscillator output clock in the prior art example of FIG. 1;

FIG. 3 is a block diagram illustrating the noise suppression scheme of the present invention as applied to an example ADPLL based DRP transmitter;

FIG. 4 is a block diagram illustrating a digital signal processor (DSP) clock timing circuit constructed in accordance with the present invention;

FIG. 5 is a timing diagram illustrating the resultant elimination of injection pulling force as a result of using the retimed frequency reference clock in accordance with the noise suppression scheme of the present invention;

FIG. 6 is a block diagram illustrating an all digital phase locked loop (ADPLL) and polar transmitter constructed in accordance with the present invention;

FIG. 7 is a block diagram illustrating the amplitude modulation (AM) path of the polar transmitter of FIG. 6;

FIG. 8 is a block diagram illustrating the time to digital converter (TDC) circuit of the present invention in more detail;

FIG. 9 is a timing diagram illustrating the waveforms generated within the time to digital converter with respect to the frequency reference clock and the RF oscillator clock;

FIG. 10 is a block diagram illustrating the noise suppression scheme of the present invention applied to a frequency correction circuit of a DCXO with sigma-delta modulation;

FIG. 11 is a block diagram illustrating the noise suppression scheme of the present invention in a DRP receiver;

FIG. 12 is a graph illustrating RMS phase error versus relative channel number in the DCS frequency band without sigma-delta dithering;

FIG. 13 is a graph illustrating RMS phase error versus relative channel number in the PCS frequency band without sigma-delta dithering;

FIG. 14 is a block diagram illustrating the FREF dither circuit of the present invention;

FIG. 15 is a block diagram illustrating the FREF delay circuit portion of the dither circuit of FIG. 11 in more detail;

FIG. 16 is a graph illustrating RMS phase error versus relative channel number in the DCS frequency band with sigma-delta dithering;

FIG. 17 is a graph illustrating RMS phase error versus relative channel number in the PCS frequency band with sigma-delta dithering;

FIG. 18 is a block diagram illustrating the FREF dither with gamma correction applied to an ADPLL; and

FIG. 19 is a timing diagram of the FREF dither with gamma correction circuit of the present invention.

### DETAILED DESCRIPTION OF THE INVENTION

### Notation Used Throughout

The following notation is used throughout this document.

| Term | Definition |
|---|---|
| A/D | Analog to Digital |
| ACW | Amplitude Control Word |
| ADPLL | All Digital Phase Locked Loop |
| AM | Amplitude Modulation |
| ASIC | Application Specific Integrated Circuit |
| CDMA | Code Division Multiple Access |
| CKR | Retimed Reference Clock |
| CKV | Variable Oscillator Clock |
| CMOS | Complementary Metal Oxide Semiconductor |
| DAC | Digital to Analog Converter |
| DCO | Digital Controlled Oscillator |
| DCS | Digital Communication Services |
| DCXO | Digitally Controlled Crystal Oscillator |
| DEM | Dynamic Element Matching |
| DRP | Digital RF Processor or Digital Radio Processor |
| DSP | Digital Signal Processor |
| FCW | Frequency Command Word |
| FPGA | Field Programmable Gate Array |
| FREF | Frequency Reference |
| GSM | Global System for Mobile Communication |
| HB | High Band |
| HDL | Hardware Description Language |
| IC | Integrated Circuit |
| IF | Intermediate Frequency |
| LB | Low Band |
| LNA | Low Noise Amplifier |
| LO | Local Oscillator |
| PCS | Personal Communication Service |
| PLL | Phase Locked Loop |
| PVT | Process Voltage Temperature |
| RF | Radio Frequency |
| RMS | Root Mean Square |
| SoC | System on Chip |
| TDC | Time to Digital Converter |
| VCO | Voltage Controlled Oscillator |
| WCDMA | Wideband Code Division Multiple Access |

### Detailed Description of the Invention

The present invention is an apparatus for and method of noise (including spurious tones) suppression in a digital radio transceiver. The invention is intended for use in a digital radio transmitter and receiver but can be used in other applications as well, such as a general communication channel. The present invention provides a solution to the injection pulling problem that plagues oscillators sensitive to interfering sources whereby a harmonic of a lower interfering frequency beats with the higher oscillator frequency causing the oscillator frequency to be pulled towards the harmonic of the lower interfering frequency. Such injection pulling is particularly noticeable in a highly integrated system on a chip (SoC) radio solution that incorporates a very large amount of digital content. The noise suppression scheme of the present invention is effective to eliminate the noise caused by the various on chip interference sources transmitted through power, ground and substrate paths. The noise suppression scheme permits an all digital PLL (ADPLL) to operate in such a way so as to avoid generating the spurs that would normally be generated from the injection pulling effect of interfering sources on the integrated circuit chip.

To aid in understanding the principles of the present invention, the description is provided in the context of a digital RF processor (DRP) transmitter and receiver that may be adapted to comply with a particular wireless communications standard such as GSM, Bluetooth, WCDMA, etc. It is appreciated, however, that the invention is not limited to use with any particular communication standard and may be used in both optical, wired and wireless applications. Further, the invention is not limited to use with a specific modulation scheme but is applicable to any modulation scheme including both digital and analog modulation. The invention is applicable in situations where it is desirable to reduce the effects of injection pulling forces on a variable oscillator.

Note that throughout this document, the term communications device is defined as any apparatus or mechanism adapted to transmit, receive or transmit and receive data through a medium. The communications device may be adapted to communicate over any suitable medium such as RF, wireless, infrared, optical, wired, microwave, etc. In the case of wireless communications, the communications device may comprise an RF transmitter, RF receiver, RF transceiver or any combination thereof.

The notation DRP is intended to denote either a Digital RF Processor or Digital Radio Processor. References to a Digital RF Processor infer a reference to a Digital Radio Processor and vice versa.

### Noise Suppression in a Digital RF Processor (DRP)

A main object of the noise suppression mechanism of the present invention is to reduce or eliminate the negative effects of injection pulling generated by interfering sources within a digital circuit on the variable oscillator. Injection pulling is particularly problematic in digital radios implemented as a system on chip having a high portion of digital logic which includes an integrated frequency synthesizer that serves as the RF oscillator whose output is used in both transmission and reception.

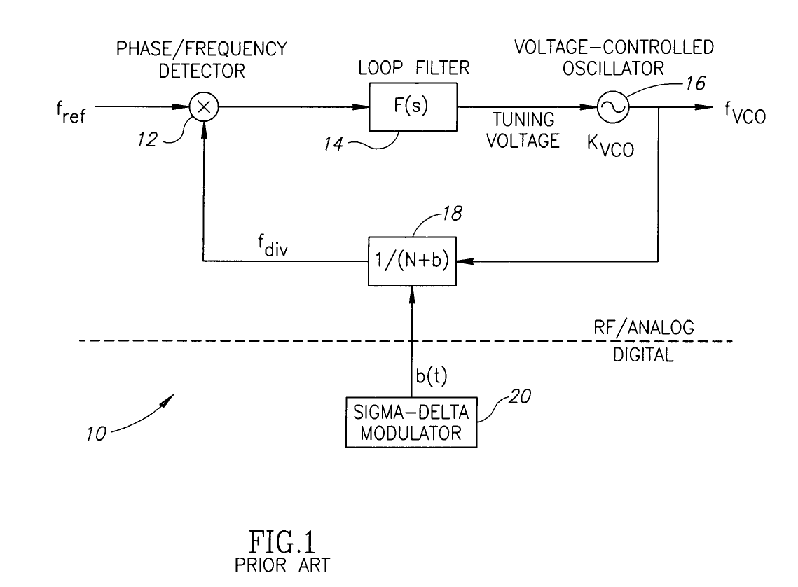

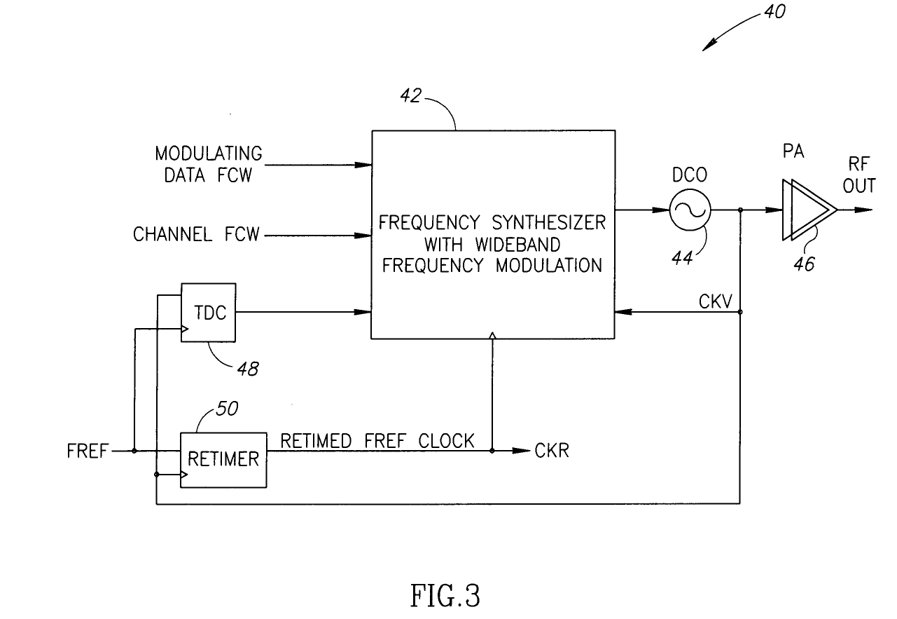

To eliminate the effects of injection pulling, the invention provides a clock retiming and synchronization scheme that is operative to retime the frequency reference source such that its clock edges are aligned (with possible fixed offset) with the RF oscillator clock edges, as described below in more detail. A block diagram illustrating the noise suppression scheme of the present invention as applied to an example ADPLL based DRP transmitter is shown in FIG. 3. The transmitter portion of the DRP, generally referenced 40, comprises a digital logic portion of a frequency synthesizer with wideband frequency modulation capability 42, digitally controlled oscillator (DCO) 44, power amplifier (PA) 46, retiming element (flip flop or register) 50 and time to digital converter (TDC) 48. For clarity sake, the blocks that are not critical to the invention are merged into the frequency synthesizer block 42. This block comprises the reference and oscillator phase accumulators, phase detector, loop filter, normalization, etc. that are illustrated in FIG. 1.

In operation, the modulating data frequency command word (FCW) and the channel FCW, both digital values, are input to the frequency synthesizer 42 which is adapted to generate a digital tuning word to the DCO. The DCO produces a digital clock CKV in the RF frequency band. The CKV clock is amplified by the PA and terminated with an antenna. In the feedback path, the CKV clock is used to retime the FREF clock. The FREF clock is the stable reference frequency clock. The FREF clock is input to the D input of a retiming element 50 (e.g., retimer, flip flop, register, etc.) and is clocked by the CKV clock. The output generated is the retimed frequency reference clock CKR. The operation of the flip flop/register serves to strip FREF of its critical timing information and generate a retimed CKR clock. It is this CKR clock that is subsequently distributed and used throughout the system. As a result of the retiming operation, the edges of the CKR clock are now synchronous with the RF oscillator clock CKV. This results in the time separation between the closest CKR and CKV edges to be time invariant.

Thus, a key aspect of the present invention is that the entire radio, including a digital RF processor, the digital baseband circuitry and the application processor, is operated in a clock synchronous mode wherein every clock in the system is either derived from or synchronized to the RF oscillator clock. Thus, the frequency reference clock is made synchronous to the oscillator clock and this retimed frequency reference clock is used to drive the entire digital logic circuitry of the SoC chip. This ensures that the different clock edges throughout the system will not exhibit mutual drift. As described in the Background Section of this document, the mutual drift of the oscillator and reference clock edges is especially damaging to the system performance of the transmitter and the receiver because it subjects the RF oscillator to injection pulling forces and causes time varying noise coupling in sampled systems.

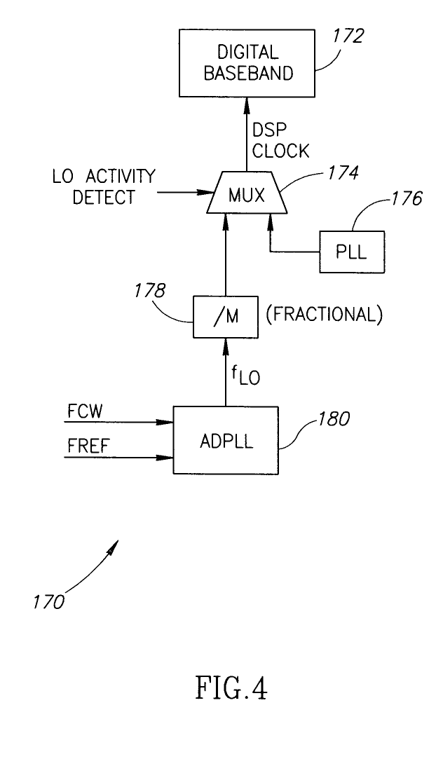

The CKR clock can be used to drive the digital logic since the digital logic is not sensitive to the accuracy of the edges, as long as the edges are compliant with the relevant timing specifications. In order to eliminate injection pulling effect in the entire chip, all the digital logic including DSP or other processors is adapted to operate on the CKR clock or clocks that are derived from or synchronous to the CKV clock. As an example, a block diagram illustrating a digital signal processor (DSP) clock timing circuit adapted to provide a processor clock that is synchronous with the RF oscillator clock (CKV clock) is shown in FIG. 4.

The example circuit, generally referenced 170, comprises an ADPLL circuit 180, fractional M divider 178, dedicated DSP local clock source 176, switching device 174 which may comprise, for example, a multiplexer, and a digital processor 172. In this example, the processor comprises the digital baseband circuit portion of a digital radio processor but may be any digital logic circuitry requiring a clock. During initial start up or reset, the switch 174 is configured to couple the local clock source (e.g., PLL or other clock source) to the processor 172. The clock generated by the local clock source is neither the CKR nor derived from or synchronous to the RF oscillator clock CKV.

The ADPLL 180 generates the local oscillator (LO) clock based on the frequency control word (FCW) and reference clock FREF inputs. The local oscillator clock is derived from or synchronous to the RF oscillator CKV clock. The local oscillator clock output from the ADPLL is input to a fractional-M divider 178. The multiplexer functions to couple either the local clock from the PLL 176 or the local oscillator clock to the processor in accordance with an LO activity detect signal. If sufficient LO activity is detected, the multiplexer is configured to couple the local oscillator clock to the processor. Otherwise, the local clock from the PLL 176 is coupled to the processor. Typically, the PLL local clock is used at start up, reset operation or occurrence of a watchdog event. The local oscillator clock signal is used during Tx and Rx operations and whenever requested by the processor.

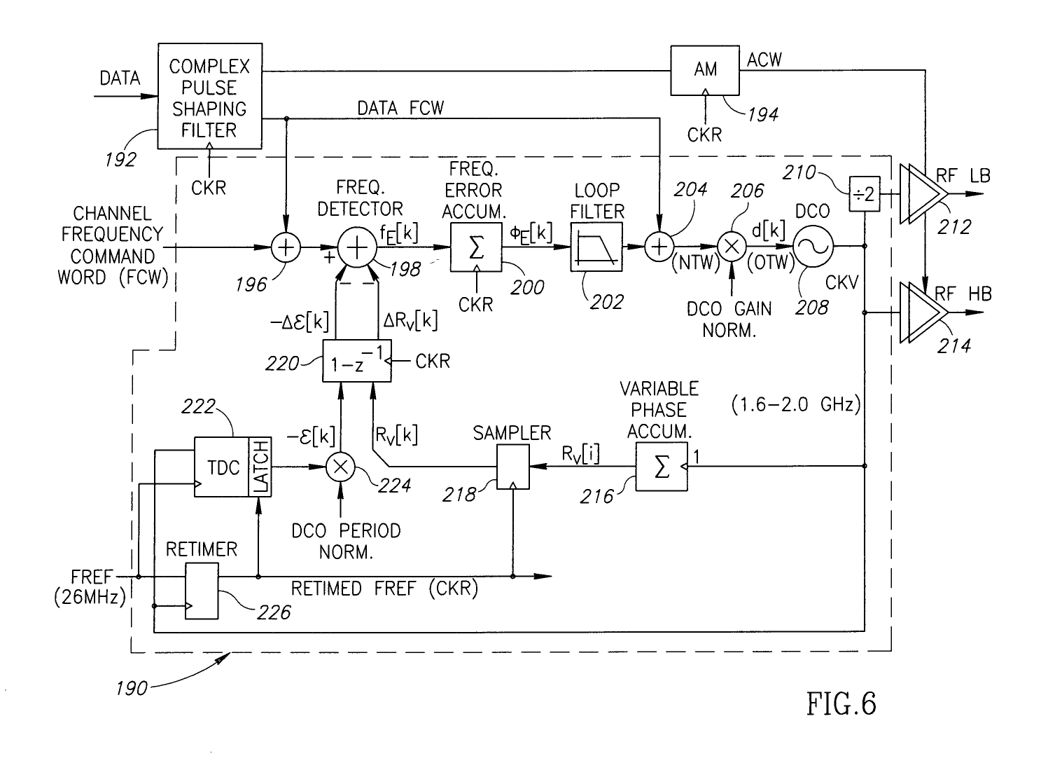

An example application of the clock retiming scheme of the present invention will now be presented. A block diagram illustrating an all digital phase locked loop (ADPLL) and polar transmitter constructed in accordance with the present invention is shown in FIG. 6. The operation of the pulse shaping block 192 and amplitude modulation (AM) block 194 is described in more detail hereinbelow. Note that the clock input to the AM block may comprise CKR clock or CKV divided clock. The core of the ADPLL is a digitally controlled oscillator (DCO) 208 adapted to generate the RF oscillator clock CKV. The oscillator core (not shown) operates at twice the 1.6-2.0 GHz high band frequency, which is then divided for precise generation of RX quadrature signals. The single DCO is shared between transmit and receive and is used for both the high frequency bands (HB) and the low frequency bands (LB). An additional 4-bits of the tracking bank are dedicated for ΣΔ dithering in order to improve frequency resolution, as described in more detail infra.

The ADPLL sequencer traverses through the process, voltage, temperature (PVT) calibration and acquisition modes during channel selection and frequency locking and stays in the tracking mode during the transmission or reception of a burst. To extend the DCO range to accommodate for voltage and temperature drifts, and to allow wide frequency modulation, the coarser-step acquisition bits are engaged by subtracting an equivalent number (generally fractional) of the tracking bank varactors. The acquisition/tracking varactor frequency step calibration is performed in the background with minimal overhead using dedicated hardware. All the varactors are realized as n-poly/n-well MOSCAP devices that operate in the flat regions of their C-V curves. The new varactors and the DCO core structure result in better phase noise which is needed to meet stricter GSM requirements.

The operation of the ADPLL in the phase-domain is as follows. The variable phase of the output is digitally represented by a fixed-point concatenation of the DCO edge transition count Rᵥ[k] and the normalized time-to-digital converter (TDC) 222 output ε[k]. As described in more detail hereinbelow, the TDC measures and quantizes the time differences between the frequency reference (FREF) and the DCO clock edges. The sampled differentiated variable phase is subtracted from the frequency command word (FCW) by the digital frequency detector 198. The frequency error f_{E}[k] samples are accumulated via frequency error accumulator 200 to create the phase error φ_{E}[k] samples, which are then filtered by loop filter 202, a fourth-order IIR filter, and normalized by a proportional loop attenuator 206.

A parallel feed with coefficient p adds an integrated term to create type-II loop characteristics, which suppresses the DCO flicker noise. The IIR filter 202 is a cascade of four single stage filters, each satisfying the following
y[k]=(1−λ)y[k−1]+λx[k] (2)
wherein
x[k] is the current input;
y[k] is the current output;
k is the time index;
λ is the configurable coefficient.

The 4-pole IIR filter attenuates the reference and TDC quantization noise at an 80 dB/dec slope, primarily to meet the GSM spectral mask requirements at 400 kHz offset. The phase error samples φ_{E}[k] are then multiplied by the f_{R}/K_{DCO} normalization factor via multiplier 206, where f_{R} is the reference frequency, to make the loop characteristics and modulation independent from the DCO gain K_{DCO}. The modulating data is injected into two points of the ADPLL to implement direct frequency modulation. A hitless gear-shifting mechanism for the dynamic loop bandwidth control serves to reduce the settling time. It changes the loop attenuator α several times during the frequency locking while adding the (α₁/α₂−1)φ₁ DC offset to the phase error, where indices 1 and 2 denote before and after the event, respectively. Note that φ₁=φ₂ since the phase is to be continuous.

The CKV clock is retimed via retimer 226, which may comprise a flip flop or register clocked by the reference frequency FREF. The output of the retimer is the retimed reference frequency clock CKR which is distributed and used throughout the device.

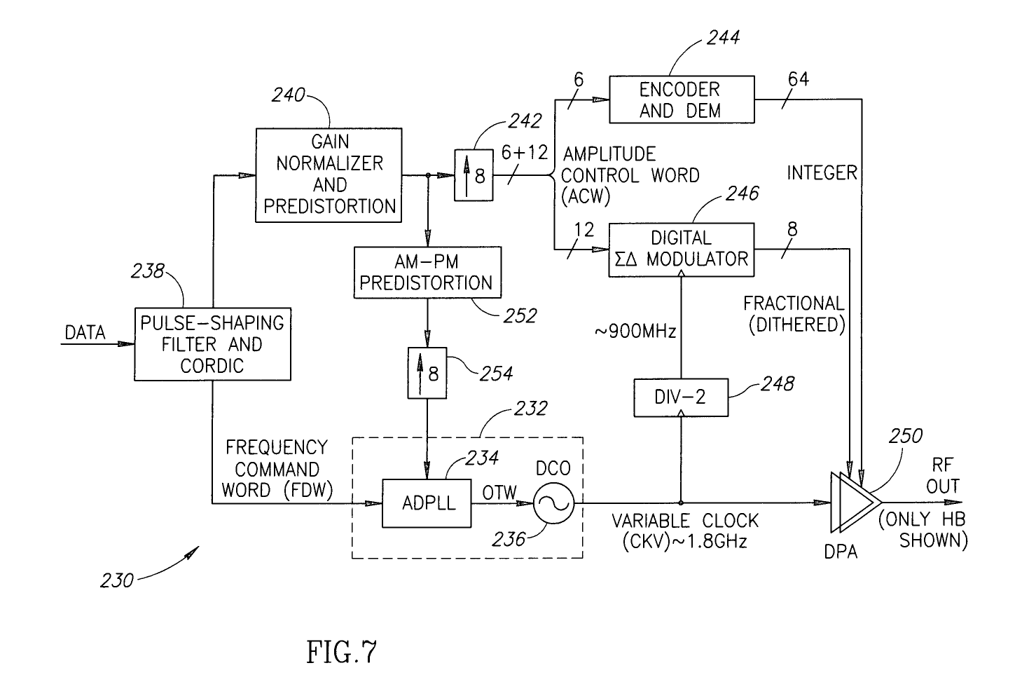

A block diagram illustrating the amplitude modulation (AM) path of the polar transmitter of FIG. 6 is shown in FIG. 7. The pulse-shaping filter 238 comprises separate I and Q filters followed by a cordic algorithm to convert the data to polar-domain phase and amplitude outputs. In this example, the sampling rate is 3.25 MHz and is interpolated up to 26 MHz to further smoothen the modulating signals. The phase is differentiated to fit the FCW input frequency format of the ADPLL 234. The amplitude output is multiplied by the step size of the digitally-controlled power amplifier (DPA) 250 and is then AM-AM predistorted. The amplitude control word (ACW) is then converted to the 64-bit unit-weighted format of the DPA. A dedicated bank of 8 DPA transistors undergoes a 900 MHz third-order ΣΔ modulation 246 to enhance the amplitude resolution and to achieve noise spectral shaping. As in the DCO controller, the DPA controller also performs dynamic element matching (DEM) 244 to enhance the time-averaged linearity. In the GSM mode, a single Gaussian pulse shaping filter is used and the cordic circuit is bypassed. The AM path is temporarily engaged to ramp the output power to a desired level to remain fixed throughout the payload.

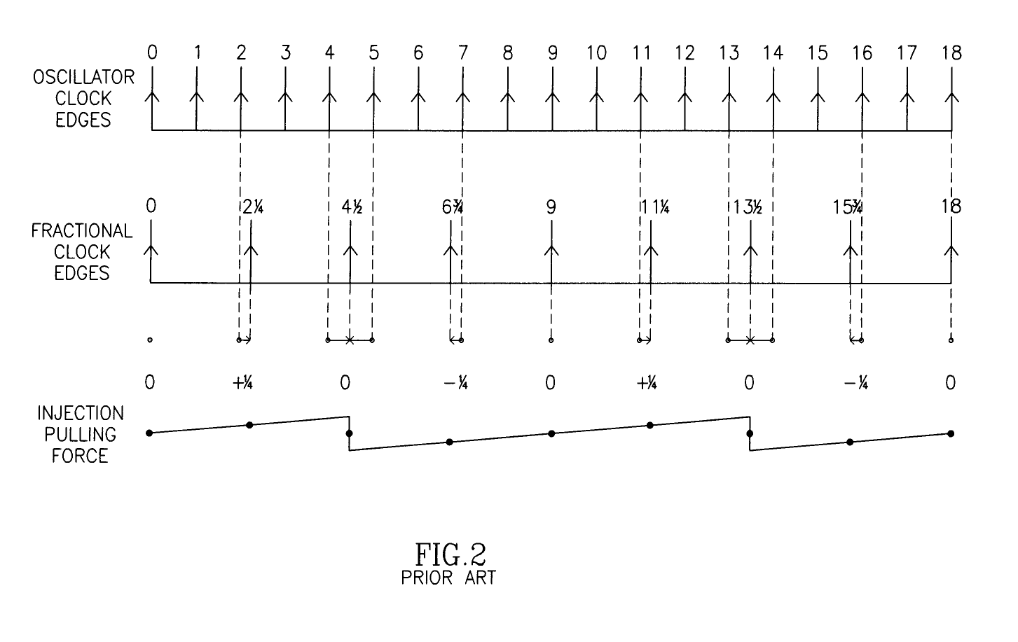

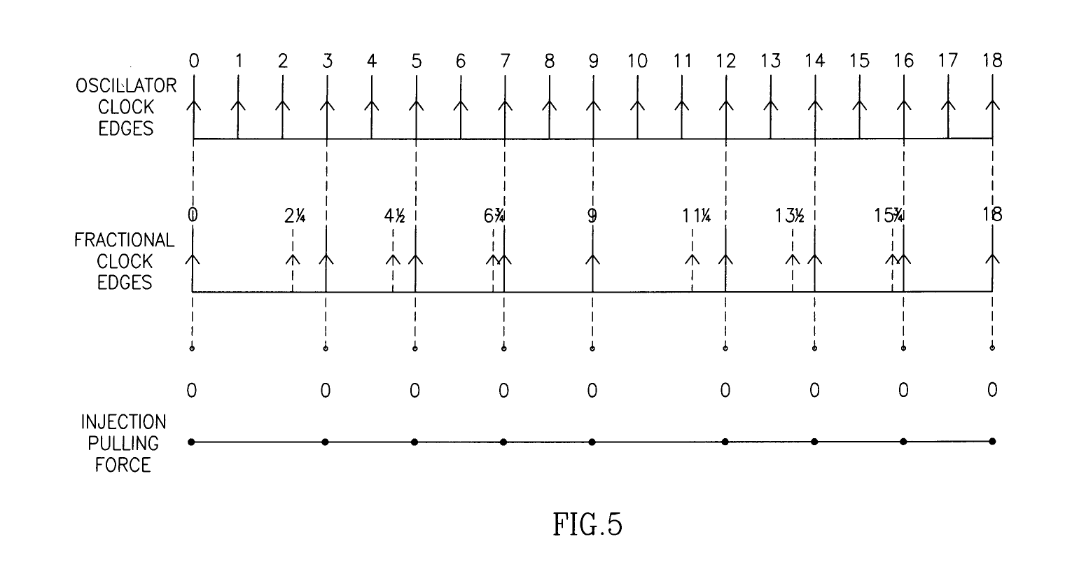

A timing diagram illustrating the resultant elimination of injection pulling force as a result of using the retimed frequency reference clock in accordance with the noise suppression scheme of the present invention is shown in FIG. 5. As in the example waveforms of FIG. 2, the RF oscillator clock frequency is 2¼ times that of the frequency reference (FREF) clock (i.e. the fractional clock). The waveforms of FIG. 4 illustrate the edges of the retimed FREF after application of the clock retiming scheme of the present invention. The positive RF oscillator clock edges are shown in the upper waveform and the retimed FREF fractional clock edges are shown in the middle waveform. The resultant injection pulling force is shown in the lower waveform. It is noted that the injection pulling force is reduced to zero and thus completely eliminated. This is achieved as a result of the retiming of the FREF edges so they are aligned (i.e. their timing relationship is fixed) with the RF oscillator edges. This eliminates any beating frequency from arising. The dashed vertical arrowed lines indicate where the original FREF edges would have occurred without clock retiming of the present invention.

It is important to note that the CKR clock (i.e. fractional clock or retimed FREF clock) in FIG. 4 has the same average frequency as the original FREF clock. The retiming operation only shifts the edges of the FREF clock but their expected averaged distances are not affected. Note also that the edges of the FREF clock are always aligned with the next rising edge of the CKV clock since it an edge event cannot be re-aligned in past time, but only in future time.

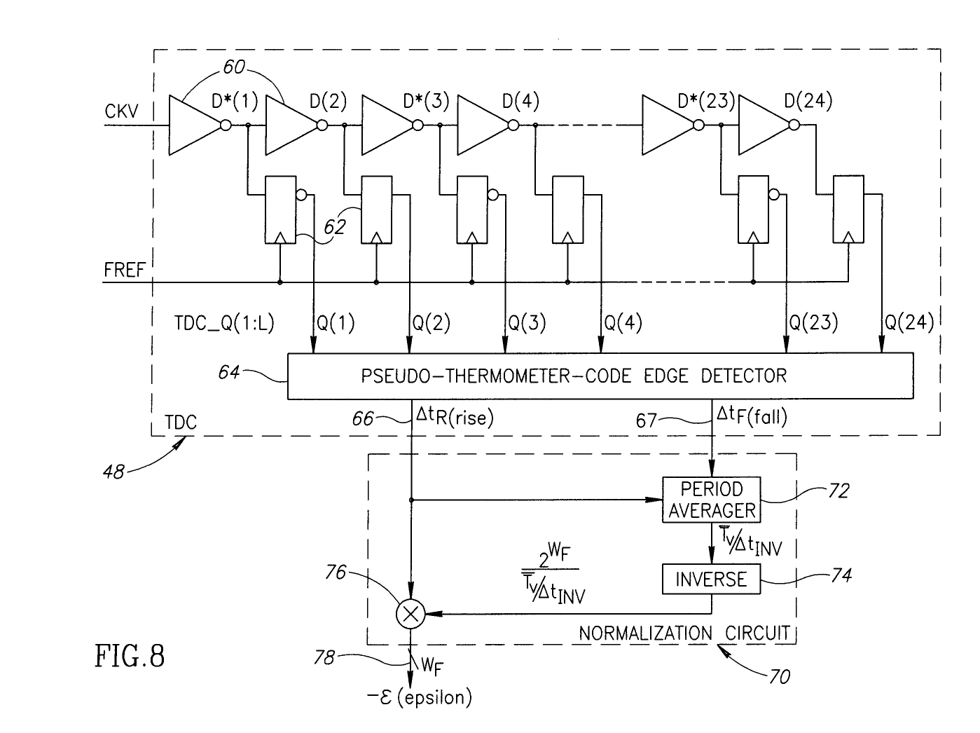

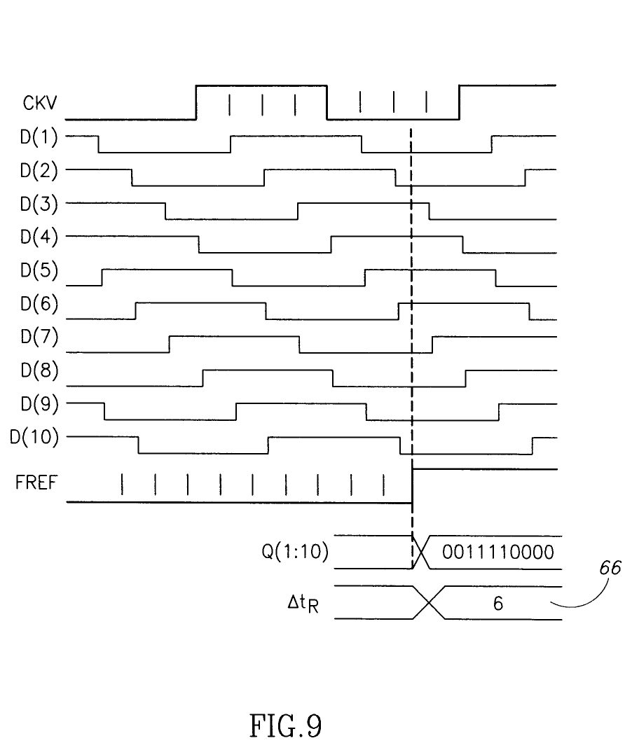

Although the invention is operative to realign the FREF clock, the original frequency reference (FREF) clock is not changed. The original frequency reference clock is used to extract timing information by way of a time to digital converter (TDC). A block diagram illustrating the time to digital converter (TDC) circuit of the present invention in more detail is shown in FIG. 8. A timing diagram illustrating the waveforms generated within the time to digital converter with respect to the frequency reference clock and the RF oscillator clock is shown in FIG. 9. The time to digital converter (TDC) 48 is operative to determine the FREF retiming quantization error. In order to meet typical wireless standards, the nature of the DCO operation within the ADPLL calls for a relatively fine phase quantization resolution requirement. It is the role of the TDC to correct the resolution limited integer-domain quantization error by means of a fractional-period error estimator. The fractional delay difference between the frequency reference clock FREF and the next significant edge of the DCO clock CKV is measured by the TDC.

With reference to FIGS. 8 and 9, the TDC is constructed as an array of inverter delay elements 60 and registers 62. In this example, the delay comprises 24 inventers but may be modified to any length depending on the requirements of the particular application. The digital fractional phase is determined by passing the DCO oscillator clock CKV through the chain of inverters such that each inverter output produces a clock slightly delayed from the previous inverter. The staggered clock phases D(1) through D(24) are then sampled by the same frequency reference clock FREF. This is accomplished by an array of registers whose Q and Q bar outputs, Q(1) through Q(24), form a pseudo thermometer code which is input to the pseudo-thermometer code edge detector 64. As a result of this arrangement, there will be a series of ones and zeros presented to the input of the detector 64.

In the example presented in FIG. 9, the period of the CKV clock is eight periods, i.e. T_{V}=8. There is a series of four ones which starts at position 3 and extends to position 6. The series of four zeros follow starting at index 7. The position of the detected transition from 1 to 0 indicates a quantized time delay Δtᵣ from the rising edge of the DCO clock CKV to the FREF sampling edge. Similarly, the position of the detected transition from 0 to 1 indicates a quantized time delay Δt_{f} from the falling edge of the DCO clock CKV to the FREF sampling edge. In this example, the pseudo thermometer code edge detector is operative to output a Δt_{R} signal 66 having a value of 6. The pseudo thermometer code edge detector also outputs a Δt_{F} signal 67. The Δt_{R} signal represents the difference between the rising edge of FREF and the previous rising edge of CKV expressed in multiples of tᵢₙᵥ, the time delay of an inverter. The Δt_{F} signal represents the difference between the rising edge of FREF and the previous falling edge of CKV. The Δt_{R} value is subsequently normalized and used by the phase detector to correct the tuning word input to the DCO. The normalization circuit 70 comprises a period averager 72, inverse function 74 and multiplier 76. The output of the TDC is normalized by the DCO clock period T_{V} before it is input to the PLL loop. Note that it has been found that accumulating 128 clock cycles by the averager is sufficient to produce an accuracy within 1 ps of the inverter delay tᵢₙᵥ.

The combination of the arithmetic phase detector and the TDC can be considered a replacement of a conventional phase/frequency detector. Since all the circuitry in the ADPLL system uses the delayed, retimed version CKR of the FREF clock except for the TDC and the clock retiming circuitry, which uses the original FREF clock, there will be a quiet time period during the TDC sampling period. The invention thus exploits a time-causal relationship between the FREF and CKR clocks. The critical continuous-domain time-difference conversion to a digital word by the TDC is performed at the FREF edge event. The FREF clock is then resampled (i.e. retimed) by the CKV clock edges to generate the CKR clock. The digital processing of almost the entire chip, including the ADPLL, is performed at the following CKR edge event or synchronously with the other CKV events.

Thus, the invention forces the digital logic circuitry on the chip to be quiet at the time the FREF edge event arrives. Once the time difference has been measured by the TDC, the tens or hundreds of thousands of gates of digital circuitry can operate with the consequent noise generation from ringing, etc.

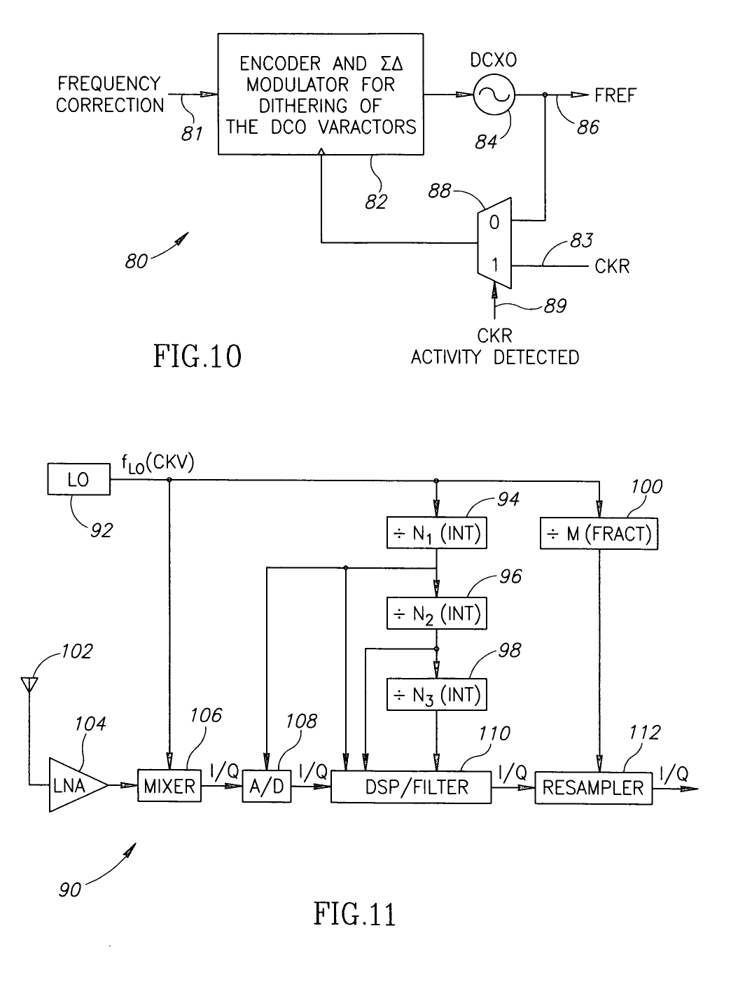

One application of the noise clock retiming scheme of the present invention will now be described. A block diagram illustrating the noise suppression scheme of the present invention applied to a frequency correction circuit of a DCXO with sigma-delta dithering is shown in FIG. 10. The digitally controlled crystal oscillator (DCXO) circuit, generally referenced 80, comprises a frequency correction signal 81, encoder and sigma-delta modulator 82, DCXO core 84 and multiplexer 88.

In the embodiment presented, the amount of circuitry operating strictly on the FREF clock in the FREF originating from the digitally controlled crystal oscillator (DCXO) circuit is minimized by clocking the digital logic with the retimed frequency reference clock. The purpose of the DCXO is to generate the frequency reference clock FREF. In order to correct the oscillation frequency of the crystal, the capacitative load presented to the crystal is set digitally. Adjusting the capacitance affects the oscillation frequency of the crystal. In the case of a cellular handset, compensation of the crystal is assisted through the base station. The base stations are typically timed to an upper stratum clock derived from an atomic clock. They transmit a very stable frequency to the handset via a carrier frequency, i.e. the so called pilot channel as in GSM, CDMA, etc.). The handset continuously compares the two frequencies through downconversion of the pilot signal with the local oscillator and makes adjustment in a closed loop manner.

In operation, a number of discrete capacitors are added to the circuit. These capacitors or varactors are integrated on the same IC. Circuitry for performing sigma-delta dithering of the varactors is incorporated within the encoder 82. Even with a small sized varactor, the dithering is needed to overcome the large step size of the capacitance. The output of the DCXO is the FREF clock which is normally used to drive the rest of the circuitry. Driving the digital logic circuitry on FREF, however, incurs the unwanted injection pulling forces. Therefore, in accordance with the present invention, the digital logic operation of encoding and sigma-delta dithering is performed using the CKR clock 83, i.e. the retimed FREF clock, rather than the FREF clock. This serves to minimize the amount of circuitry operating at the original FREF edge events. Thus, the DCXO related digital circuitry operates on the clock that is synchronous to the DCO and thus does not contribute to the injection pulling. In order to avoid problem at power on or reset operations, the digital logic 82 can use the FREF clock for bootstrapping purposes. A multiplexer 88 determines which clock the encoder circuitry uses based on a CKR activity detect control signal 89. Alternatively, the control signal can be created from the RX/TX mode provided the clock watchdog activity is not asserted.

A second application of the noise clock retiming scheme of the present invention will now be described. A block diagram illustrating the noise suppression scheme of the present invention of a DRP receiver is shown in FIG. 11. This embodiment provides the means for generating an arbitrary frequency clock by dividing the RF oscillator edges using a fractional-N divider. The embodiment comprises utilizing the directly derived RF oscillator clock whereby the digital receive data path circuitry is operated on a simple divide by integer-N clock. The sample rate conversion from a channel dependent rate to a fixed rate of the symbol multiple is performed by an interpolator or resampler. All the clocks used are generated using an integer or fractional division of the local oscillator.

The DRP receiver, generally referenced 90, connects to an antenna 102, and comprises a low noise amplifier (LNA) 104, mixer 106, an analog filter, and optional variable gain amplifier (VGA), analog to digital converter (A/D) 108, digital signal processor (DSP)/filter 110, resampler block 112, local oscillator (LO) 92, integer clock dividers 94, 96, 98 and fractional (also possible integer) divider 100. A key feature of the receiver 90 is that all the digital circuitry is synchronous and operates off clocks that are derived from or synchronous to the CKV clock, i.e. the RF oscillator clock. Using clocks that are directly derived from the RF oscillator clock by clock edge division prevents injection pulling forces from arising. In general, the purest oscillator in the overall solution is the LO which meets very tough standards on the phase noise performance. This means that the clock has smallest amount of jitter conceivable in any oscillator in the entire system. Using this pure clock as the clock input to analog discrete time blocks such as sigma-delta A/D converter results in two advantages; first, lowest jitter clocks are used that improves the achievable dynamic range from the analog block and second, ultra high speed clocks can be easily obtained that drive very high over-sampling analog blocks. The disadvantage of this approach is that the discrete time data sequence at the output of these analog blocks has a data rate that is directly related to the channel that the receiver tunes to. In general, the range of channels occupy up to 10% of variation around the center of the band. Hence, plus or minus 5% variation in data rates need to be accommodated by the subsequent circuits.

The sampling operation performed by the RF mixer 106 is not adversely affected for the following reason; first, the performance of a receiver has a bottle-neck imposed by the jitter on LO which determines the dynamic range achievable at the mixer output. By using the same source and providing integer division of these clocks to other analog blocks ensures that we are not further degrading the performance since we are using the same clock source. If a separate oscillator is used to generate the clocks for subsequent analog blocks after the mixer, the jitter on this clock will have to be as good as the jitter on the LO and even if that is the case, its jitter cannot be correlated to the jitter on the LO. Furthermore, the downstream digital blocks in the receive path comprise a large number of digital gates that are clocked synchronously to the RF oscillator. During the RF sampling process, these signals cause interference and cause a certain amount of voltage or charge perturbation to accumulate on the sampling capacitor. The clock trees are also excited in harmony with the LO and the perturbance caused by switching of the clock trees creates tones that are harmonically related and fold on top of each other as the data rates are decimated along the chain. If these perturbances were scattered all over the clock period, it would generate random noise floor that will degrade the receiver performance. However, by careful frequency planning, one can ensure that the spurs lie outside of the channel bandwidth of interest. Therefore, since the sampling clock is the RF oscillator clock, the amount of perturbation will remain constant and may be treated as a small DC offset that may be easily compensated for. If, however, the downstream digital logic used a nonsynchronous clock, i.e. N_{f}≠0, the amount of perturbation would be time variant and exhibit itself as a spurious tones.

Considering a cellular application as an example, the LO frequency (which represents the CKV clock rather than the FREF clock) is 2,000 MHz and the N₁=N₂=4 and N₃=64. Assume a 2 GHz signal is received at the antenna and input to the LNA. The output of the LNA is mixed down to a low IF frequency on the order of 100 kHz which is input to the sigma-delta A/D converter which might operate at a very high frequency such as 500 MHz, for example. This results in a large oversampling ratio of about 2500. Thus, using CKV, with its staggered edge events does not effect the performance. Decimation is then performed to reduce the high data rate from 500 MHz to about 2 MHz. Preferably, the decimation is performed using powers of two, simplifying the clock generation. The disadvantage of the sampling rate (i.e. ˜2 MHz) of the DSP/filter is that it is channel dependent. Therefore, if, for example, the channel frequency changes by 200 kHz, the sampling rate will track it due to the divide by 1024 (4×4×64) relationship. Thus, a change in the channel frequency of 200 kHz would result in a change in the sampling rate at the DSP of about 200 Hz.

Note that the decimated frequencies are all created by division of the variable CKV clock (i.e. the LO clock) hence they are synchronous to the CKV clock. Thus, the use of the fixed rate FREF clock is avoided altogether thus avoiding the problems associated with injection pulling caused by use of the FREF clock which would degrade the performance of the transmitter and receiver. Integer divisions of the LO clock result in a digital data stream whose sample rate is channel dependent. The instantaneous frequency is not fixed causing the sampling rate to vary. For a given channel, however, it is fixed. For different channels, the sampling rate can change hundreds of kilohertz but stays a relatively fixed 2 MHz without much variation. In accordance with the present invention, the sampling rate is made channel independent by adjusting the sample rate using a resampler 112 driven by a fractional M divider 100. The fractional divider compensates for the use of a variable clock in the receiver circuitry rather than a fixed clock. Present software algorithms of the digital baseband work best for a specific symbol oversampling ratio. For example, for the 270.8333 kS/s symbol rate in GSM, the digital baseband is designed to operate at 541.6667 kHz sampling rate or at exactly two samples per symbol.

If the LO frequency increases, then the sampling rate at the DSP will be somewhat higher and in order to maintain the same frequency at the output, the fractional division ratio at the resampler is reduced proportionately. The resampler functions to convert the channel dependent data stream to a fixed symbol rate data stream using well-known interpolation techniques. The fractional M divider generates an average fractional frequency clock equal to the symbol rate multiple whose edges are obtained by integer division.

It is possible to generate a constant rate clock at the output of the resampler while the input clock is directly derived from the LO and at the same time ensure that the rising edges of the constant rate clock only occur in synchronism with the rising edges of the LO. This elaborates the concept of synchronous fractional division. The main idea is that the output clock rate is maintained to a fixed value by dropping pulses of input clock such that on an average a fixed constant rate output clock is obtained. A counter counts the number of clocks at the input side and its count value is used to drop pulses at the output of a divider. The divider operates in synchronism to the CKV clock or LO but misses pulses at the output such that a constant rate is maintained at the output. The key fact is that the clocks derived from this method by integer divisions on the output side of the resampler will have rising edges aligned and synchronous with the rising edges of the LO. Despite, for any LO frequency, we can still obtain the same constant output rate by dropping appropriate number of pulses.

### FREF Dither Circuit with Gamma Correction

As described hereinabove, the FREF retiming quantization error is determined by the time to digital converter (TDC) 48 (FIG. 8). As shown in FIG. 8, the TDC is constructed as an array of inverters and registers and functions to measure the fractional delay difference between the reference clock and the next rising edge of the oscillator clock. The resolution of this delay difference is a single inverter delay Δtᵢₙᵥ which typically can be considered the most stable logic level delay and may be better than 40 ps depending on the particular process. Such an inverter delay results in a GSM quality phase detection mechanism.

The TDC operates by passing the oscillator clock (CKV) through the chain of inverters wherein the delayed clock is then sampled by the FREF clock using an array of registers whose outputs form a pseudo-thermometer code. The TDC output is normalized by the oscillator clock period T_{V} before being input to the phase locked loop.

The TDC quantization operation, however, does have an affect on the phase noise at the output of the ADPLL. Considering the phase noise spectrum at the RF output of the ADPLL reveals that the TDC phase noise contribution can be minimized by improving the TDC timing resolution and increasing the sampling rate.

There are two potential internal sources of noise: the first is the oscillator itself and the second is due to TDC operation of calculating ε (epsilon), i.e. the timing delay difference. It is noted that other than these two sources of internal phase noise, the system, due to its digital nature, is relatively immune from any time-domain or amplitude-domain perturbations and does not contribute to the phase noise.

The phase noise generated by the operation of the TDC is due to fact that even though the TDC is a digital circuit, the FREF and CKV inputs are continuous in the digital domain. The TDC error comprises several components including quantization errors, non-linearity errors and random errors due to thermal effects. The TDC quantization noise, however, is the predominant of the three components.

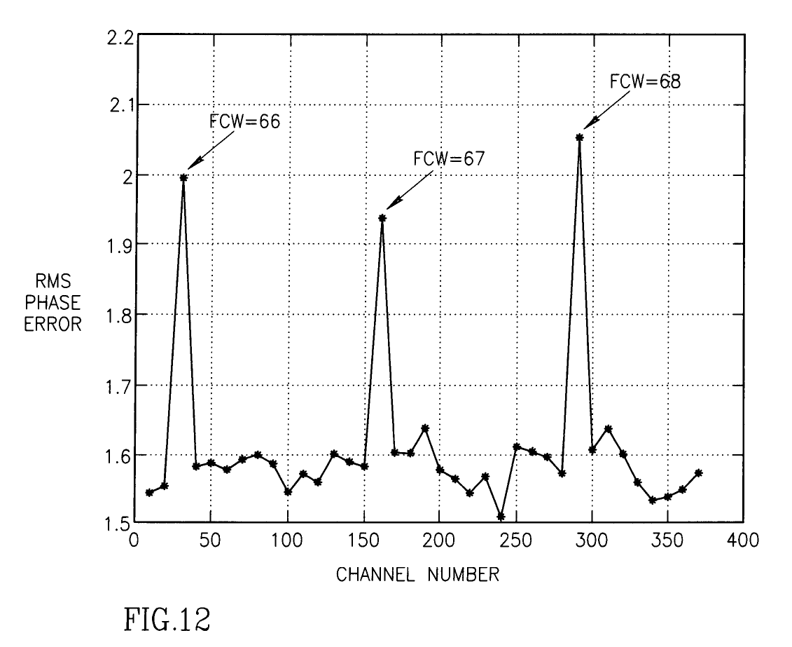

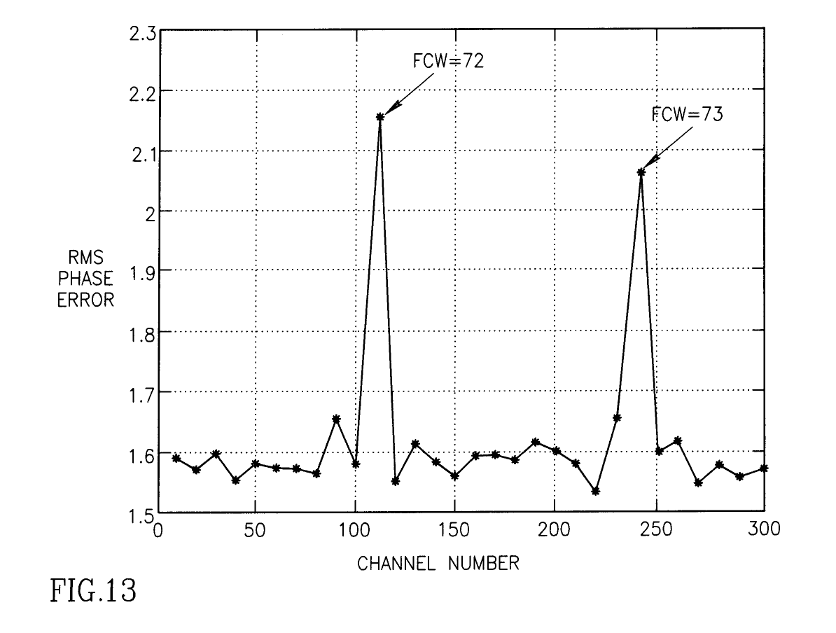

A graph illustrating RMS phase error of the DRP transmitter versus relative channel number in the DCS frequency band without sigma-delta dithering of the present invention is shown in FIG. 12. A graph illustrating RMS phase error of the DRP transmitter versus relative channel number in the PCS frequency band without sigma-delta dithering of the present invention is shown in FIG. 13. As can be seen in FIGS. 12 and 13, the phase error spikes are caused by ill-conditioned TDC behavior at integer-N values of the channel number.

In accordance with the present invention, a solution to this problem is to randomize the instantaneous value of the timing difference using well-known sigma-delta modulation techniques such that the reference clock FREF is dithered before being input to the TDC. A block diagram illustrating the FREF dither circuit of the present invention is shown in FIG. 11. The FREF dither circuit, generally referenced 120, comprises a delay circuit 122 and a ΣΔ (sigma-delta) MASH modulator 124. The FREF clock 125 is input to the delay circuit which is operative to output a dithered version 126 of the FREF clock. The delay circuit applies a delay to the FREF signal in accordance with a delay control signal 129 generated by the sigma-delta modulator 124. An input code 127 determines the amount of dithering to be applied to the FREF signal.

Note that the sigma-delta modulator may be any order depending on the requirements of the particular application. In the example presented herein, the modulator is a 5^{th} order sigma-delta MASH modulator. A constant input code to the sigma-delta modulator results in a high-speed unit weighted 32-bit output whose time-averaged value equals that of the input. The power spectral density of the output is noise shaped with the quantization energy rising at higher frequencies.

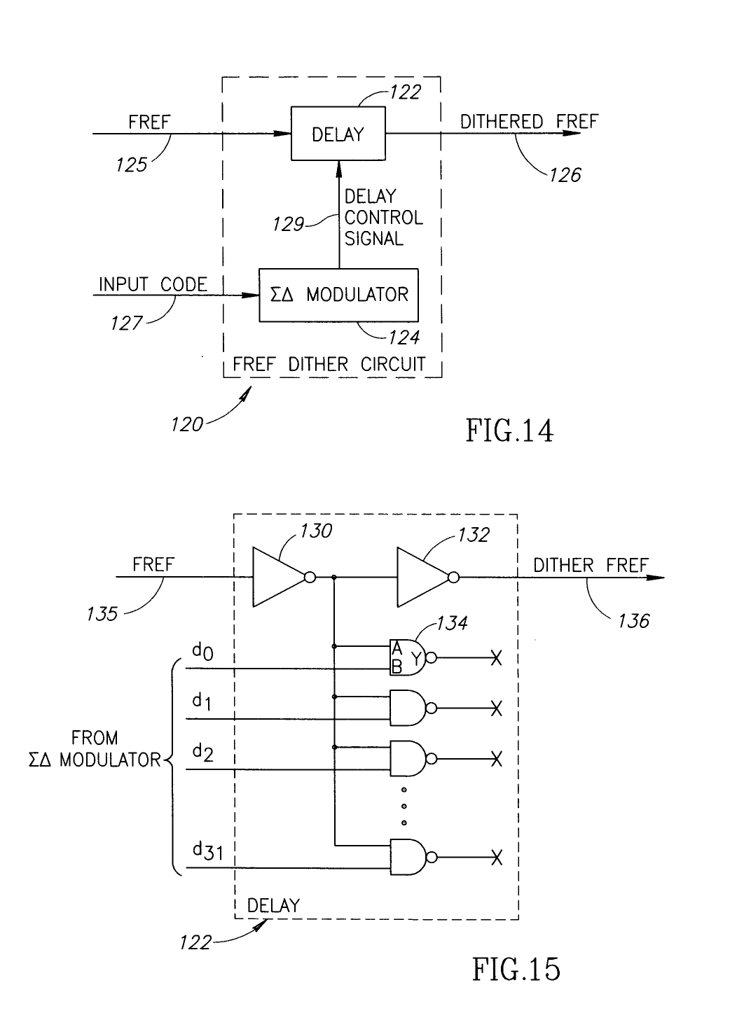

A block diagram illustrating the FREF delay circuit portion of the dither circuit of FIG. 14 in more detail is shown in FIG. 15. The delay circuit 122 comprises inverters 130, 132 and a plurality of gates 134. In this 5^{th} order example, there are 32 NAND gates, each NAND gate having A and B inputs and a Y output. The 32-bit sigma-delta modulator delay control output functions to control the delay of the FREF clock signal by changing the cumulative capacitance of the A-input of each of the 32 NAND gates by virtue of the state of their B-input. The Y outputs are left unconnected. Note that the static delay generated by the delay circuit does not impact performance since the ADPLL is operative to correct for it automatically.

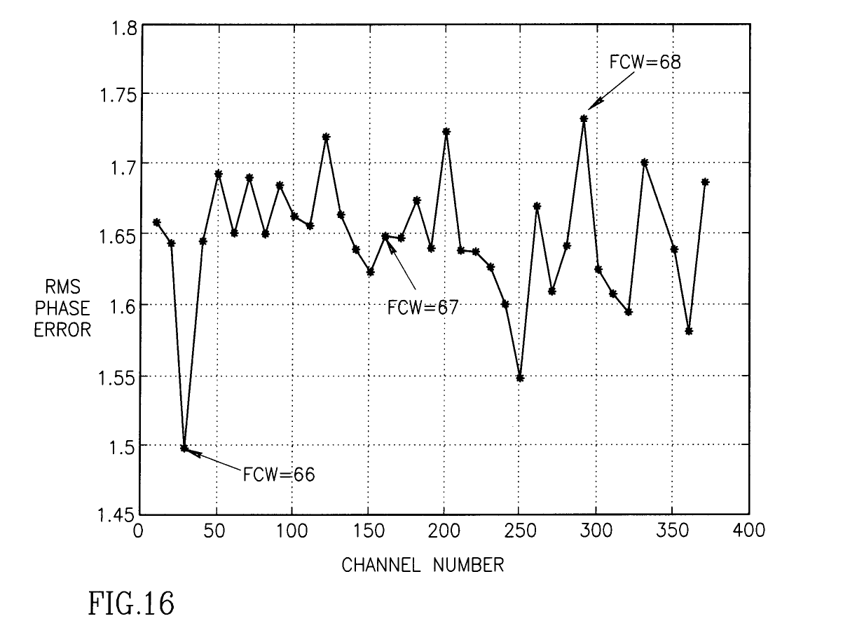

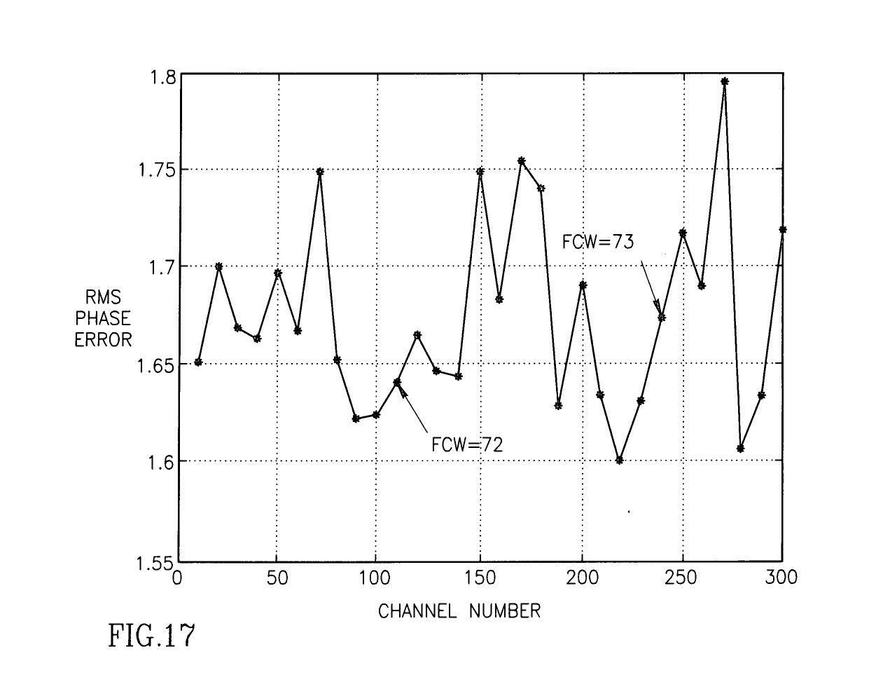

A graph illustrating RMS phase error of the DRP transmitter versus relative channel number in the DCS frequency band with sigma-delta dithering in accordance with the present invention is shown in FIG. 16. A graph illustrating RMS phase error of the DRP transmitter versus relative channel number in the PCS frequency band with sigma-delta dithering in accordance with the present invention is shown in FIG. 17. These graphs assume 4^{th} order 5-bit MASH sigma-delta dithering, a constant input code word of 13/32 and a unit delay of 15 ps. It is noted that as a result of using sigma-delta dithering of the FREF clock in accordance with the present invention, the ill-conditioned behavior at integer-N channel numbers is substantially reduced.

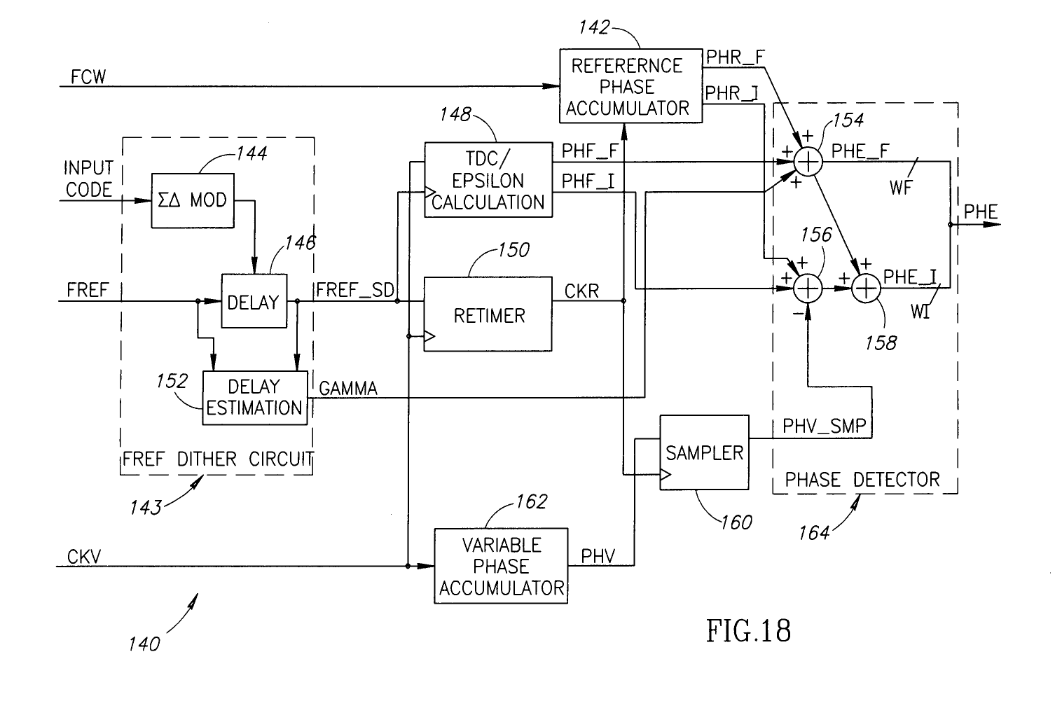

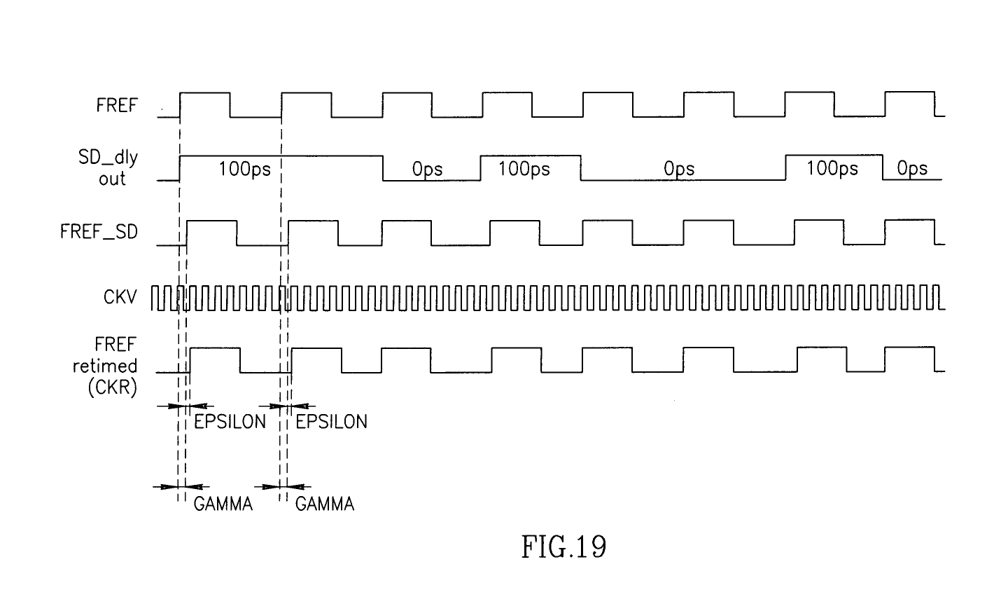

A block diagram illustrating the FREF dither with gamma correction applied to an ADPLL is shown in FIG. 18. A timing diagram of the FREF dither with gamma correction circuit of the present invention is shown in FIG. 19. The circuit, generally referenced 140, comprises an FREF dither circuit 143, TDC/epsilon calculation circuit 148, retimer 150, reference phase accumulator 142, variable phase accumulator 162, sampler 160 and phase detector 164. The FREF dither circuit 143 comprises sigma-delta modulator 144, delay circuit 146 and delay estimation circuit 152. The phase detector 164 comprises adders 154, 156 and 158.

With reference to FIGS. 18 and 19, in operation, the gamma correction circuit reduces the amount of quantization noise by predicting the FREF delay and compensating for it at the phase detector stage. The delay estimation circuit 152 functions to estimate the value gamma which is the fractional timing difference between the FREF clock and the dithered FREF clock (FREF_SD), i.e. the sigma-delta delay correction. The dithered FREF clock is input to the TDC which is operative to calculate the value of epsilon which is the fractional timing difference between the dithered FREF clock and the oscillator clock CKV. It results from the retiming of the dithered FREF clock with the CKV clock. The epsilon calculation outputs two quantization error entities: PHF_F (a fractional portion) and PHF_I (an integer portion). The retimer 150 functions to retime the dithered FREF clock so that its edges are aligned with the oscillator clock CKV. The retimed dithered FREF clock CKR drives the remainder of the system.

The fractional error components PHF_F generated by the TDC, PHR_F generated by the reference phase accumulator and the gamma value generated by the delay estimation circuit are added via adder 154 in the phase detector. Similarly, the integer error components PHF_I generated by the TDC, PHR_I generated by the reference phase accumulator and the sampled PHV derived from the variable phase accumulator are added via adder 156 in the phase detector. The fractional and integer phase error sums are combined to yield the phase error PHE output from the phase detector. The phase error PHE output of the phase detector can be expressed as
PHE=[PHR_{—}I(k)−PHV_{—}SMP(k)]+[PHR_{—}F(k)+epsilon(k)+gamma(k)] (3)
where
PHR_I(k) is the integer portion of the reference phase;
PHV_SMP(k) is the variable phase from the CKV domain;
PHR_F(k) is the fractional portion of the reference phase;
epsilon(k) is the fractional error correction;
gamma(k) is the sigma-delta delay correction.

It is intended that the appended claims cover all such features and advantages of the invention that fall within the spirit and scope of the present invention. As numerous modifications and changes will readily occur to those skilled in the art, it is intended that the invention not be limited to the limited number of embodiments described herein. Accordingly, it will be appreciated that all suitable variations, modifications and equivalents may be resorted to, falling within the spirit and scope of the present invention.

1. A method of suppressing noise in a communications device, said communications device including a variable radio frequency (RF) oscillator and a frequency reference clock, said method comprising the steps of:
retiming said frequency reference clock so as to generate a retimed frequency reference clock, whereby edges of said retimed frequency reference clock are synchronous to edges of an RF oscillator clock generated by said variable RF oscillator; and
operating said communications device in a clock synchronous manner wherein clocks in said communications device are derived from or synchronous to said retimed frequency reference clock.

2. The method according to claim 1, further comprising the step of determining quantization error of said frequency reference clock at frequency reference clock edge events that occur during a quiet time period of said communications device due to a time causal relationship between said frequency reference clock and said retimed frequency reference clock.

3. The method according to claim 1, wherein said step of operating said communications device in a clock synchronous manner forces circuitry within said communications device to be in an inactive quiet state at occurrences of frequency reference clock edge events.

4. The method according to claim 1, wherein use of said retimed frequency reference clock enables quiet sampling within a time to digital converter as a result of delaying clocks utilized by digital logic within said communications device.

5. The method according to claim 1, wherein said step of retiming said frequency reference clock comprises the step of delaying frequency reference clock edge events until the nearest RF oscillator clock edge event thereby eliminating injection pulling forces on said RF oscillator clock caused by said frequency reference clock.

6. The method according to claim 1, wherein the time separation between closest retimed frequency reference clock edges and RF oscillator clock edges is time invariant.

7. The method according to claim 1, adapted to be implemented in an Application Specific Integrated Circuit (ASIC).

8. The method according to claim 1, adapted to be implemented in a Field Programmable Gate Array (FPGA).

9. An apparatus for suppressing noise in a communications device, said communications channel including a variable radio frequency (RF) oscillator and a frequency reference clock, comprising:
means for retiming said frequency reference clock so as to generate a retimed frequency reference clock, whereby edges of said retimed frequency reference clock are synchronous to edges of an RF oscillator clock generated by said variable RF oscillator; and
means for operating said communications device in a clock synchronous manner wherein clocks in said communications device are derived from or synchronous to said retimed frequency reference clock.

10. The apparatus according to claim 9, further comprising a time to digital converter adapted to determine a quantization error of said frequency reference clock at frequency reference clock edge events that occur during a quiet time period of said communications device due to a time causal relationship between said frequency reference clock and said retimed frequency reference clock.

11. The apparatus according to claim 9, wherein said means for operating said communications device in a clock synchronous manner forces circuitry within said communications device to be in an inactive quiet state at occurrences of frequency reference clock edge events.

12. The apparatus according to claim 9, wherein use of said retimed frequency reference clock enables quiet sampling within a time to digital converter as a result of delaying clocks utilized by digital logic within said communications device.

13. The apparatus according to claim 9, wherein said means for retiming said frequency reference clock is adapted to delay frequency reference clock edge events until the nearest RF oscillator clock edge event thereby eliminating injection pulling forces on said RF oscillator clock caused by said frequency reference clock.

14. The apparatus according to claim 9, wherein said means for retiming said frequency reference clock comprises a flip flop, wherein said RF oscillator clock is coupled to a clock input of said flip flop, said frequency reference clock is coupled to a data input of said flip flop and wherein said flip flop is operative to generate said retimed frequency reference clock at the output thereof.

15. The apparatus according to claim 9, wherein the time separation between closest retimed frequency reference clock edges and RF oscillator clock edges is time invariant.

16. The apparatus according to claim 9, adapted to be implemented in an Application Specific Integrated Circuit (ASIC).

17. The apparatus according to claim 9, adapted to be implemented in a Field Programmable Gate Array (FPGA).

18. An apparatus for suppressing noise in a digital radio transceiver, comprising:
a variable radio frequency (RF) oscillator adapted to generate an RF oscillator clock;
a frequency reference clock;
retiming circuitry for generating a retimed frequency reference clock from said frequency reference clock, whereby edges of said retimed frequency reference clock are made synchronous to edges of said RF oscillator clock; and
clock circuitry for providing only clocks to digital circuitry within said radio transceiver that are edge synchronous with said RF oscillator.

19. The apparatus according to claim 18, wherein NO—IT IS OK providing only clocks to digital circuitry within said radio transceiver that are edge synchronous with said RF oscillator eliminates the injection pulling effects of said frequency reference clock on said RF oscillator clock.

20. The apparatus according to claim 18, wherein said retiming circuitry comprises a flip flop having an input, output and clock input, wherein said RF oscillator clock is coupled to said clock input, said frequency reference clock is coupled to said input and wherein said flip flop is operative to generate said retimed frequency reference clock at the output thereof.

21. The apparatus according to claim 18, wherein the operation of said retiming circuitry causes the time separation between closest retimed frequency reference clock edges and RF oscillator clock edges to be time invariant.

22. The apparatus according to claim 18, wherein providing only clocks to digital circuitry within said radio transceiver that are edge synchronous with said RF oscillator forces digital circuitry within said radio transceiver to be in an inactive quiet state at occurrences of frequency reference clock edge events.

23. The apparatus according to claim 18, wherein use of said retimed frequency reference clock by digital circuitry within said radio transceiver enables quiet sampling within a time to digital converter incorporated within said radio transceiver.

24. The apparatus according to claim 18, adapted to be implemented in an Application Specific Integrated Circuit (ASIC).

25. The apparatus according to claim 18, adapted to be implemented in a Field Programmable Gate Array (FPGA).

26. A method of suppressing noise in a communications device, said communications device including a frequency reference clock and a variable radio frequency (RF) oscillator adapted to generate an RF oscillator clock, said method comprising the steps of:
extracting timing information from said frequency reference clock;
determining a timing error as a function of said RF oscillator clock and said timing information extracted from said frequency reference clock;
generating a retimed frequency reference clock by stripping timing information from said frequency reference clock and aligning edges of said frequency reference clock along edges of said RF oscillator clock; and
driving digital logic circuitry within said communications device with said retimed frequency reference clock.

27. The method according to claim 26, wherein said step of determining said timing error occurs at frequency reference clock edge events thereby creating a quiet time period of said communications device due to the time causal relationship between said frequency reference clock and said retimed frequency reference clock.

28. The method according to claim 26, wherein said step of driving comprises the step of operating said communications device in a clock synchronous thereby forcing digital circuitry within said communications device to be in an inactive quiet state at occurrences of frequency reference clock edge events.

29. The method according to claim 26, wherein said step of driving enables quiet sampling within a time to digital converter as a result of delaying clocks utilized by digital logic within said communications device.

30. The method according to claim 26, wherein said step of generating a retimed frequency reference clock comprises the step of delaying frequency reference clock edge events until the nearest RF oscillator clock edge event thereby eliminating injection pulling forces on said RF oscillator clock caused by said frequency reference clock.

31. The method according to claim 26, adapted to be implemented in an Application Specific Integrated Circuit (ASIC).

32. The method according to claim 26, adapted to be implemented in a Field Programmable Gate Array (FPGA).

33. An apparatus for controlling a digitally controlled crystal oscillator (DCXO) in a digital radio transceiver, comprising:
clock means for generating a retimed frequency reference clock to be synchronous with an RF oscillator clock, said retimed frequency reference clock generated by aligning edges of a frequency reference clock along edges of said RF oscillator clock;
frequency correction circuitry operative to generate a first control signal to said DCXO wherein said frequency correction circuitry operates either on said frequency reference clock or on said retimed frequency reference clock; and
switching means coupled to said frequency correction circuitry, said switching means operative to switch between said frequency reference clock and said retimed frequency reference clock in accordance with a second control signal.

34. The apparatus according to claim 33, wherein said switching means is configured to output said frequency reference clock upon power up or reset of said radio transceiver.

35. The apparatus according to claim 33, wherein said switching means is configured to output said frequency reference clock if a watchdog event is asserted.

36. The apparatus according to claim 33, wherein said switching means is configured to output said retimed frequency reference clock at particular points in time during operation of said communications device.

37. The apparatus according to claim 33, wherein said switching means is configured to output said retimed frequency reference clock when said radio transceiver is transmitting or receiving.

38. A radio receiver, comprising:
a local oscillator clock whose frequency varies with the particular channel selected;
an integer clock divider operative to generate at least one clock utilizing integer division;
a processor for processing a received signal to generate a data stream whose sample rate is channel dependent;
a fractional-M clock divider operative to generate a fractional clock; and
means for resampling said data stream utilizing said fractional clock to generate an output data stream whose sampling rate is independent of said selected channel.

39. The radio receiver according to claim 38, wherein said local oscillator clock comprises a retimed frequency reference clock.

40. The radio receiver according to claim 38, wherein said local oscillator clock is adapted to be synchronous with an RF oscillator clock.

41. The radio receiver according to claim 38, wherein said local oscillator clock is derived from an RF oscillator clock.

42. The radio receiver according to claim 38, adapted to be implemented in an Application Specific Integrated Circuit (ASIC).

43. The radio receiver according to claim 38, adapted to be implemented in a Field Programmable Gate Array (FPGA).

44. An apparatus for generating a processor clock in a communications device, comprising:
clock means operative to generate a local oscillator clock signal as a function of a frequency control word (FCW) and a reference frequency clock;
a fractional M divider adapted to fractionally divide said local oscillator clock signal to yield a divided local oscillator clock signal; and
switching means operative to switch either said divided local oscillator clock signal or a local clock signal to a clock input of said processor.

45. The apparatus according to claim 44, wherein said switching means is controlled by a local oscillator activity detect signal whereby said switching means is configured to couple said divided local oscillator clock signal to said processor when local oscillator activity is detected.

46. The apparatus according to claim 44, wherein said switching means is configured to output said local clock signal upon power up or reset of said communications device.

47. The apparatus according to claim 44, wherein said switching means is configured to output said local clock signal if a watchdog event is asserted.

48. The apparatus according to claim 44, wherein said switching means is configured to output said local oscillator clock signal at particular points in time during operation of said communications device.

49. The apparatus according to claim 44, wherein said switching means is configured to output said local oscillator clock signal when said communications device is transmitting or receiving.

50. The apparatus according to claim 44, wherein said switching means is configured to output said local oscillator clock signal upon request from said processor.

51. The apparatus according to claim 44, wherein said local oscillator clock signal generated by aligning edges of said frequency reference clock along edges of an RF oscillator clock.

52. The apparatus according to claim 44, wherein said processor clock is adapted to provide clock timing for a Digital Signal Processor (DSP).

53. The apparatus according to claim 44, wherein said processor clock is adapted to provide clock timing for a digital baseband circuit in a digital RF processor (DRP).

54. A method for generating a processor clock for a digital processor in a communications device, comprising:
generating a local oscillator clock signal as a function of a frequency control word (FCW) and a reference frequency clock, wherein said local oscillator clock signal is adapted to be synchronous with an RF oscillator clock, said local oscillator clock signal generated by aligning edges of said frequency reference clock along edges of said RF oscillator clock;
fractionally dividing said local oscillator clock signal to yield a divided local oscillator clock signal; and
switching either said divided local oscillator clock signal or a local clock signal to a clock input of said processor in accordance with a local oscillator activity detect signal whereby said divided local oscillator clock signal is coupled to said processor when local oscillator activity is detected.

55. The method according to claim 54, wherein said step of switching comprises the step of coupling said local clock signal to the clock input of said processor upon power up or reset of said communications device.

56. The method according to claim 54, wherein said step of switching comprises the step of coupling said divided local oscillator clock signal to the clock input of said processor if a watchdog event is asserted.

57. The method according to claim 54, wherein said step of switching comprises the step of coupling said divided local oscillator clock signal to the clock input of said processor at particular points in time during operation of said communications device.

58. The method according to claim 54, wherein said step of switching comprises the step of coupling said divided local oscillator clock signal to the clock input of said processor when said communications device is transmitting or receiving.

59. The method according to claim 54, wherein said processor clock is adapted to provide clock timing for a Digital Signal Processor (DSP).

60. The method according to claim 54, wherein said processor clock is adapted to provide clock timing for a digital baseband circuit in a digital RF processor (DRP).

61. An apparatus for improving resolution quality in a time to digital converter, comprising:
a delay circuit operative to receive a reference clock and delay said reference clock in accordance with a delay control signal so as to generate a dithered reference clock therefrom;
a randomization circuit adapted to generate said delay control signal; and
wherein said dithered reference clock is input to said time to digital converter to yield randomization of the instantaneous value of a timing difference generated by said time to digital converter.

62. The apparatus according to claim 61, wherein said delay circuit comprises a plurality of gates, wherein said delay control signal determines the delay of said reference clock by modifying the input capacitance of said plurality of said gates.

63. The apparatus according to claim 61, wherein said randomization circuit comprises a sigma-delta MASH modulator adapted to generate said delay control signal whose time averaged value is substantially equal to said input code.

64. The apparatus according to claim 63, wherein said sigma-delta MASH modulator comprises a 5^{th} order sigma-delta MASH modulator.

65. The apparatus according to claim 61, wherein said randomization is operative to generate said delay control in response to an input code.

66. A method of improving resolution quality in a time to digital converter, comprising:
generating a sigma-delta modulated delay control signal;
delaying a reference clock signal in accordance with said delay control signal to output a dithered reference clock signal thereby; and
inputting said dithered reference clock signal to said time to digital converter resulting in randomization of the instantaneous value of a timing difference generated by said time to digital converter.

67. The method according to claim 66, wherein said step of delaying comprises the step of modifying the input capacitance of a plurality of gates coupled to said reference clock signal.

68. The apparatus according to claim 66, wherein said sigma-delta modulated delay control signal is generated using a 5^{th} order sigma-delta MASH modulator.

69. The apparatus according to claim 68, wherein the time averaged value of said delay control signal is substantially equal to said input code.

70. The apparatus according to claim 66, wherein said sigma-delta modulated delay control signal is generated in response to an input code.
